(19) United States
(12) Patent Application Publication
(10) Pub. No.: US 2009/0053844 A1
(43) Pub. Date: Feb. 26, 2009

(54) METHOD FOR FABRICATING PIXEL STRUCTURE

(75) Inventors: Ming-Yuan Huang, Hsinchu (TW); Chih-Chun Yang, Hsinchu (TW); Han-Tu Lin, Hsinchu (TW); Chih-Hung Shih, Hsinchu (TW); Ta-Wen Liao, Hsinchu (TW); Chin-Yueh Liao, Hsinchu (TW); Chia-Chi Tsai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/050,928

(22) Filed: Mar. 18, 2008

(30) Foreign Application Priority Data
Aug. 24, 2007 (TW) 96131441

(51) Int. Cl. H01L 33/00

(52) U.S. Cl. 438/38; 257/E33.064

(57) ABSTRACT

A method for fabricating a pixel structure is provided. A substrate having a gate thereon is provided. Next, a gate dielectric layer is formed to cover the gate. A channel layer is formed on the gate dielectric layer above the gate. A source and a drain are formed on the channel layer at two sides of the gate, wherein the gate, the channel layer, the source and the drain constitute a thin film transistor (TFT). A passivation layer is formed on the gate dielectric layer and the TFT. A first shadow mask exposing parts of the passivation layer is provided thereabove. The drain is exposed by a laser applied via the first shadow mask to partially remove the passivation layer. A conductive layer is formed to cover the passivation layer and the drain. The conductive layer is then automatically patterned by the patterned passivation layer to form a pixel electrode.

### CROSS-REFERENCE TO RELATED APPLICATION

This, application claims the priority benefit of Taiwan application serial no. 96131441, filed on Aug. 24, 2007. The entirety the above-mentioned patent application is hereby incorporated by reference herein and made a part of specification.

### BACKGROUND OF THE INVENTION

1. Field of the Invention

The present invention generally relates to a method for fabricating a pixel structure, particularly to a method for fabricating a passivation layer of a pixel structure through a laser ablation process.

2. Description of Related Art

A display serves as a communication interface between humans and machines, and the flat panel display (FPD) is the mainstream of displays. The flat panel display mainly includes: organic electroluminescence display (OELD), plasma display panel (PDP), and thin film transistor liquid crystal display (TFT-LCD), wherein the TFT-LCD is the most extensively adopted. Generally speaking, the TFT-LCD is primarily constituted by a TFT array substrate, a color filter array substrate and a liquid crystal layer. The TFT array substrate includes a plurality of scan lines, a plurality of data lines and a plurality of pixel structures arranged in array. Each of the pixel structures is electrically connected to a corresponding scan line and a corresponding data line respectively.

FIG. 1A through 1G are schematic views of a conventional method for fabricating a pixel structure. First, referring to FIG. 1A, a substrate 10 is provided, and a gate 20 is formed thereon via a first photolithography and etching process (PEP). Next, referring to FIG. 1B, a gate dielectric layer 30 is formed on the substrate 10 to cover the gate 20. Afterwards, referring to FIG. 1C, a channel layer 40 is formed on the gate dielectric layer 30 above the gate 20 via a second photolithography and etching process.

Generally speaking, the material of the channel layer 40 is amorphous silicon. Next, referring to FIG. 1D, a source 50 and a drain 60 are formed on a portion of the channel layer 40 and a portion of the gate dielectric layer 30 via a third photolithography and etching process. It is illustrated in FIG. 1D that the source 50 and the drain 60 extend respectively from two sides of the channel layer 40 to the gate dielectric layer 30 and expose a portion of the channel layer 40. Referring to FIG. 1E, a passivation layer 70 is formed on the substrate 10 to cover the gate dielectric layer 30, the channel layer 40, the source 50 and the drain 60. Referring to FIG. 1F, the passivation layer 70 is then patterned to form a contact hole H therein via a fourth photolithography and etching process. FIG. 1F illustrates the contact hold H in the passivation layer 70 exposes a portion of the drain 60. Referring to FIG. 1G, a pixel electrode 80 is formed on the passivation layer 70 via the fourth photolithography and etching process. As shown in FIG. 1G, the pixel electrode 80 is electrically connected to the drain 60 via the contact hole H. Upon formation of the pixel electrode 80, the fabrication of a pixel structure 90 is accomplished.

As described above, it requires five photolithography and etching processes to fabricate the conventional pixel structure 90. In other words, five photo-masks having different patterns are required to fabricate the pixel structure 90. Since photo-masks are quite expensive, the fabrication cost of the pixel structure 90 cannot be reduced when the number of photolithography and etching processes is not decreased.

In addition, as the size of the photo-mask for fabricating TFT array substrates increases along with the size of the TFT-LCD panel, the fabrication price of large-sized photo-masks would be even more expensive such that the fabrication cost of the pixel structure 90 cannot be effectively reduced.

### SUMMARY OF THE INVENTION

The present invention is directed to a method for fabricating a pixel structure which is capable of reducing the fabrication cost.

In order to specifically disclose the present invention, a method for fabricating a pixel structure is provided. The method includes providing a substrate first and forming a gate thereon. Then, a gate dielectric layer is formed on the substrate to cover the gate. Afterwards, a channel layer is formed on the gate dielectric layer above the gate. Next, a source and a drain are formed on the channel layer at two sides of the gate, wherein the gate, the channel layer, the source and the drain constitute a thin film transistor (TFT). Further, a passivation layer is formed on the gate dielectric layer and the TFT. A first shadow mask is provided above the passivation layer, and the first shadow mask exposes a portion of the passivation layer. Then, a laser is applied to irradiate the passivation layer via the first shadow mask so as to remove a portion of the passivation layer and expose the drain. Next, a conductive layer is formed to cover the passivation layer and the exposed drain, and the conductive layer is automatically patterned by the patterned passivation layer to form a pixel electrode.

The present invention is directed to another method for fabricating a pixel structure. In the method, a substrate is provided first, and then a TFT is formed thereon. Afterwards, a passivation layer is formed on the TFT, and a first shadow mask is provided above the passivation layer. The first shadow mask exposes a portion of the passivation layer. Then, a laser is applied to irradiate the passivation layer via the first shadow mask so as to remove a portion of the passivation layer and expose the drain. Next, a conductive layer is formed to cover the passivation layer and the exposed drain, and the conductive layer is automatically patterned by the patterned passivation layer to form a pixel electrode.

In an embodiment of the present invention, the method for fabricating the pixel structure further includes baking the patterned passivation layer after the patterned passivation layer is formed so that the patterned passivation layer has a mushroom-shaped top surface. The mushroom-shaped top surface of the patterned passivation layer is greater than the bottom surface thereof.

In an embodiment of the present invention, the aforesaid method for forming the gate may include the following steps. First, a first metal layer is formed on the substrate. Then, the first metal layer is patterned to form the gate. According to another embodiment of the present invention, the method for forming the gate may include the following steps. First, a first metal layer is formed on the substrate, and then a second shadow mask above the first metal layer is provided. The second shadow mask exposes a portion of the first metal layer. Afterwards, a laser is applied to irradiate the first metal layer via the second shadow mask so as to remove the portion of the first metal layer exposed by the second shadow mask.

In an embodiment of the present invention, a method for forming the channel layer may include the following steps. First, a semiconductor layer is formed on the substrate, and then the semiconductor layer is patterned to form the channel layer.

According to another embodiment of the present invention, the method for forming the channel layer may include the following steps. First, a semiconductor layer is formed on the substrate, and then providing a third shadow mask above the semiconductor layer. The third shadow mask exposes a portion of the semiconductor layer. Afterwards, a laser is applied to irradiate the semiconductor layer via the third shadow mask so as to remove the portion of the semiconductor layer exposed by the third shadow mask.

In an embodiment of the present invention, a method for forming the source and the drain may include the following steps. First, a second metal layer is formed on the channel layer and the gate dielectric layer, and then the second metal layer is patterned to form the source and the drain.

According to an embodiment of the present invention, a method for forming a conductive layer includes sputtering an indium tin oxide (ITO) layer or an indium zinc oxide (IZO) layer.

According to an embodiment of the present invention, the power of the laser applied to irradiate the passivation layer may be between about 10 mJ/cm² and about 500 mJ/cm², and the wavelength of the laser may be between about 100 nm and about 400 nm.

According to an embodiment of the present invention, the mushroom-shaped top surface of the patterned passivation layer may be greater than the bottom surface thereof.

According to an embodiment of the present invention, the method further includes removing the patterned passivation layer after forming the pixel electrode.

According to an embodiment of the present invention, the method further includes forming a capacitor-bottom electrode while forming the gate simultaneously, and forming a capacitor-top electrode while forming the source and the drain simultaneously. The capacitor-bottom electrode and the capacitor-top electrode constitute a storage capacitor.

In the present invention, the fabricating of the pixel electrode is automatically accomplished while the conductive layer is formed simultaneously via a proper patterned passivation layer. Therefore, compared with the fabricating method of the pixel structure in the prior art, the fabricating method of the present invention simplifies the fabricating steps and reduces the fabrication cost. Additionally, the shadow masks used in a laser ablation process are simpler than the conventional photo-masks. Hence, the fabrication cost of shadow masks used in the laser ablation process is much lower.

In order to make the aforementioned and other objects, features and advantages of the present invention more comprehensible, preferred embodiments accompanied with figures are described in detail below.

### BRIEF DESCRIPTION OF THE DRAWINGS

FIG. 1A through 1G are schematic views illustrating a conventional method for fabricating a pixel structure.

FIG. 2A through 2G are schematic views illustrating a method for fabricating a pixel structure in the present invention.

FIG. 3A through 3C are schematic views illustrating a laser ablation process used for forming a gate.

FIG. 4A through 4C are schematic views illustrating a method for forming a channel layer.

FIG. 5A through 5C are schematic views illustrating a method for forming a source and a drain.

FIG. 6A through 6H are schematic views illustrating a method for fabricating a pixel structure in the present invention.

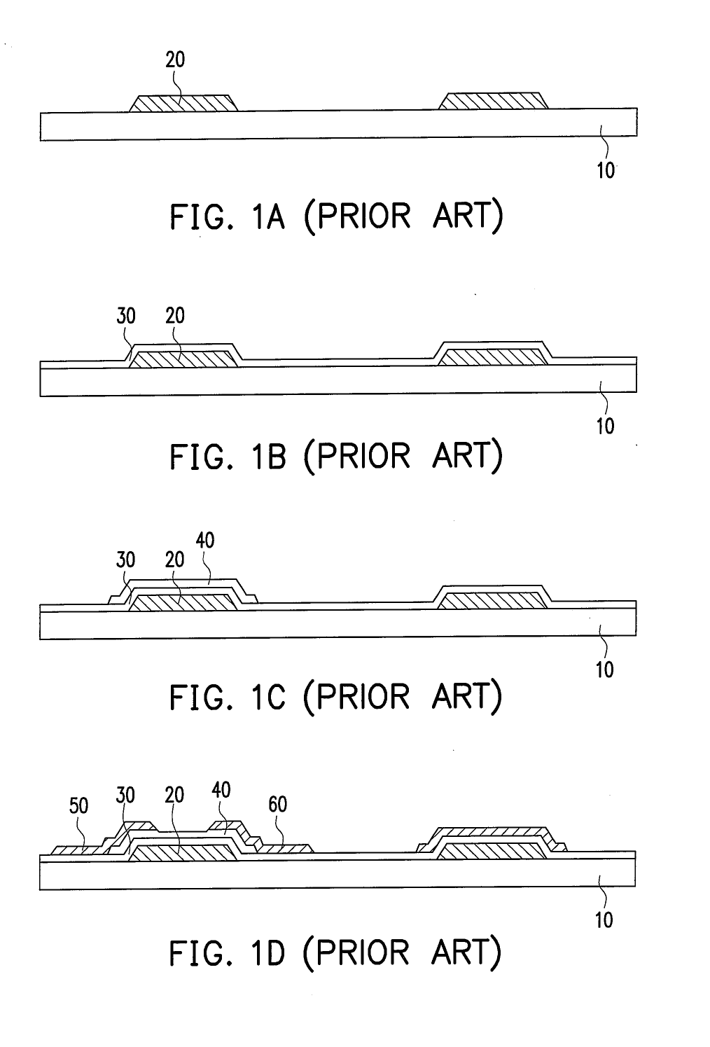

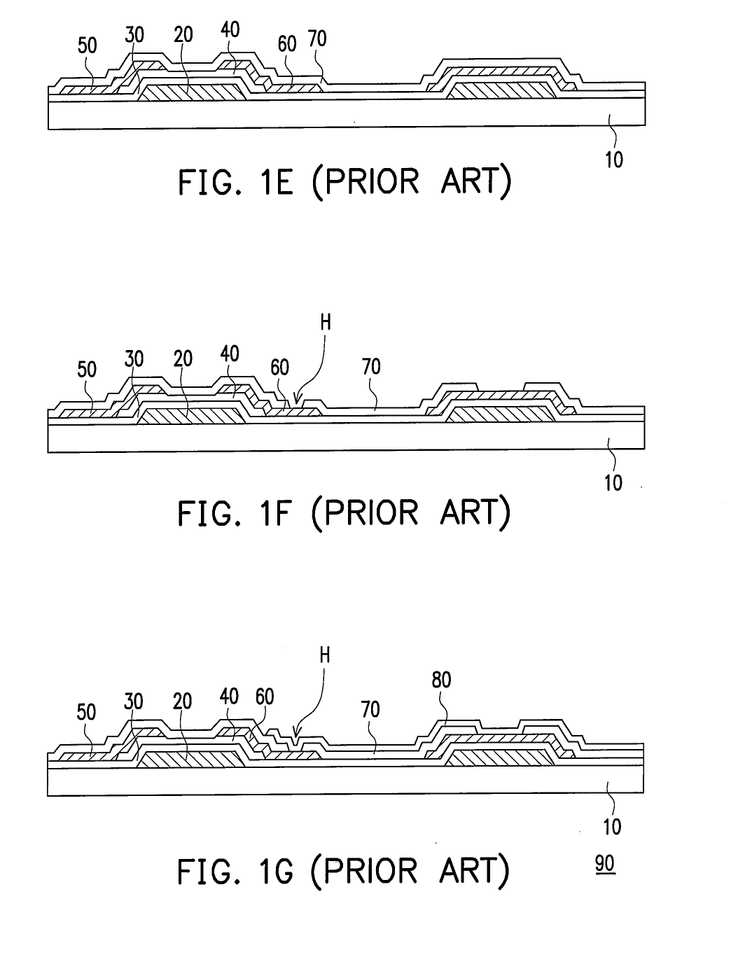

### DESCRIPTION OF EMBODIMENTS

### The First Embodiment

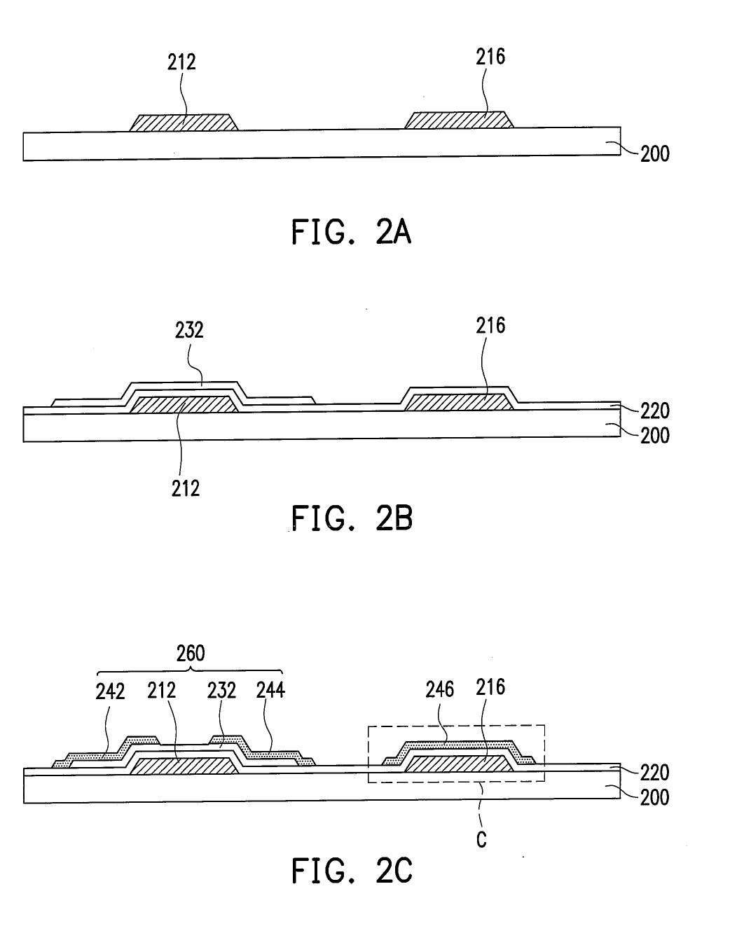

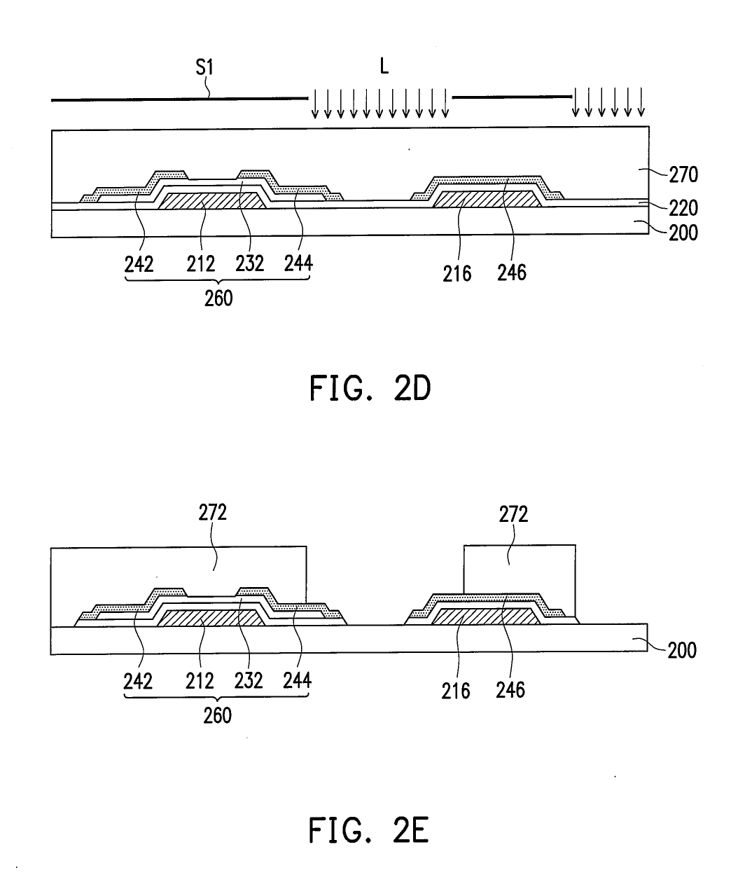

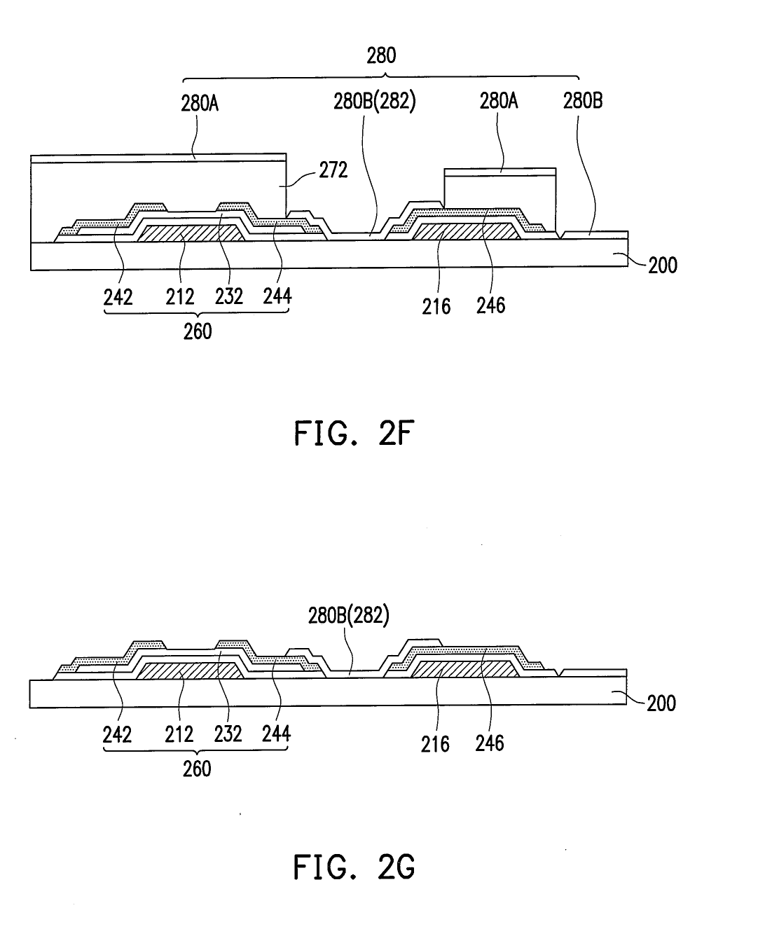

FIG. 2A through 2G are schematic views illustrating a method for fabricating a pixel structure according to the first embodiment of the present invention. Referring to FIG. 2A, a substrate 200 is provided. A material of the substrate 200 is, for example, a rigid material (e.g. glass) or a flexible material (e.g. plastic). Afterwards, a gate 212 is formed on the substrate 200. In the present embodiment, the fabricating method further includes forming a capacitor-bottom electrode 216 while forming the gate 212.

Specifically, the capacitor-bottom electrode 216 and the gate 212 are formed simultaneously through the same photolithography and etching process.

Referring to FIG. 2B, a gate dielectric layer 220 is formed on the substrate 200 to cover the gate 212 and the capacitor-bottom electrode 216. The gate dielectric layer 220 is formed, for example, by a chemical vapor deposition (CVD) process or other suitable thin film deposition processes. A material of the gate dielectric layer 220 may be a dielectric material such as silicon oxide, silicon nitride or silicon-oxy-nitride. As illustrated in FIG. 2B, a channel layer 232 is formed on the gate dielectric layer 220 above the gate 212.

Referring to FIG. 2C, a source 242 and a drain 244 are formed on the channel layer 232 at two sides of the gate 212. The gate 212, the channel layer 232, the source 242 and the drain 244 constitute a thin film transistor (TFT) 260. It should be noted that a method for fabricating the TFT 260 is not limited to the aforementioned steps.

Other suitable fabricating processes or other fabricating steps may also be applied to manufacture the TFT 260. The method for fabricating the TFT 260 of the present invention is not limited to the one described above. In addition, according to the present embodiment, the fabricating method further includes forming a capacitor-top electrode 246 above the gate dielectric layer 220 of a capacitor-bottom electrode 216 while forming the source 242 and the drain 244 as illustrated in FIG. 2C. Specifically, the capacitor-top electrode 246, the source 242 and the drain 244 are formed simultaneously through the same photolithography and etching process. The capacitor-bottom electrode 216 and the capacitor-top electrode 246 constitute a storage capacitor C so as to maintain superior display quality.

Referring to FIG. 2D, a passivation layer 270 is formed on the gate dielectric layer 220, the TFT 260 and the capacitor-top electrode 246. The passivation layer 270 may be made of an organic dielectric material such as acrylic resin and photosensitive resin, or an inorganic dielectric material such as silicon oxide, silicon nitride or silicon-oxy-nitride. The passivation layer 270 may be formed by a photoresist coating process or other suitable thin film deposition processes, such as a CVD process.

Afterwards, a first shadow mask S1 is provided above the passivation layer 270. As illustrated in FIG. 2D, the first shadow mask S1 exposes a portion of the passivation layer 270 and a laser L is applied to irradiate the passivation layer 270 via the first shadow mask S1.

Thereafter, as illustrated in FIG. 2E, after the laser L is applied via the first shadow mask S1 to remove the exposed portion of the passivation layer 270, a remaining patterned passivation layer 272 after treated by the laser L exposes the drain 244, a portion of the gate dielectric layer 220 and a portion of the capacitor-top electrode 246. In detail, after irradiated by the laser L, the passivation layer 270 would absorb energy of the laser L and be ablated from a surface of the gate dielectric layer 220 and a surface of a portion of the TFT 260. A portion of the passivation layer 270 shielded by the first shadow mask S1 is left. Preferably, the power of the laser L applied to ablate the passivation layer 270 is between about 10 mJ/cm² and about 500 mJ/cm², and a wavelength of the laser L is between about 100 nm and about 400 nm.

Still referring to FIG. 2E, the passivation layer 270 and a second metal layer 240 are then used as masks to perform an etching process such that an exposed portion of the gate dielectric layer 220 is removed to expose a portion of the substrate 200 and the first metal layer (not illustrated) on a gate pad (not illustrated) simultaneously. The characteristics that the passivation layer 270 absorbs a specific laser but other material layers hardly absorb the specific laser are applied in the present application. The laser L and the first shadow mask S1 can be used to even more effectively and thoroughly remove a portion of the passivation layer 270. Besides, the laser L and the first shadow mask S1 can avoid damages to a surface of the second metal layer 240 under the passivation layer 270 caused by a conventional etching process. As a result, the TFT can obtain better electrical characteristics so as to achieve better display quality.

Referring to FIG. 2F, a conductive layer 280 is formed to cover the patterned passivation layer 272, the exposed drain 244, a portion of the substrate 200 and a portion of the capacitor-top electrode 246. A method for forming the conductive layer 280 may be sputtering an ITO layer or an IZO layer. In FIG. 2F, since the patterned passivation layer 272 served as a bottom layer for the conductive layer 280 has a suitable thickness, two conductive layers 280A and 280B electrically insulated from each other are automatically formed while forming the conductive layer 280. In detail, a designer may properly control the thickness of the bottom layer, i.e. the patterned passivation layer 272, and utilize anisotropic characteristics of a thin film deposition process applied to the conductive layer 280 so that the two inconsecutive conductive layers 280A and 280B are formed in the conductive layer 280 in correspondence to the thickness variation of the bottom layer, the patterned passivation layer 272. One portion of the conductive layer 280, the conductive layer 280A, is formed on the patterned passivation layer 272. The other portion of the conductive layer 280, the conductive layer 280B, is formed on the substrate 200, the drain 244 and the capacitor-top electrode 246. The portion of the conductive layer 280B connected with the drain 244 is constituted as a pixel electrode 282. The pixel electrode 282 is simultaneously electrically connected to the capacitor-top electrode 246. It should be noted that in clear distinction from the prior art, the patterned passivation layer 272 is designed to have a proper thickness in the present embodiment, and the pixel electrode 282 is automatically defined while the conductive layer 280 is formed in the meanwhile.

Therefore, a photolithography and etching process is omitted in the present invention and thereby reducing complexity of the whole fabricating process.

Generally, after the pixel electrode 282 is formed, the patterned passivation layer 272 may be further removed as illustrated in FIG. 2G. A method for removing the patterned passivation layer 272 includes, for example, applying a stripper on the surface of the patterned passivation layer 272 so that a bottom surface of the patterned passivation layer 272 can be ablated from the surface of the TFT 260 and the surface of the capacitor-top electrode 246 because the stripper permeates into the bottom surface of the passivation layer 272. A portion of the conductive layer 280A above the patterned passivation layer 272 can also be removed altogether.

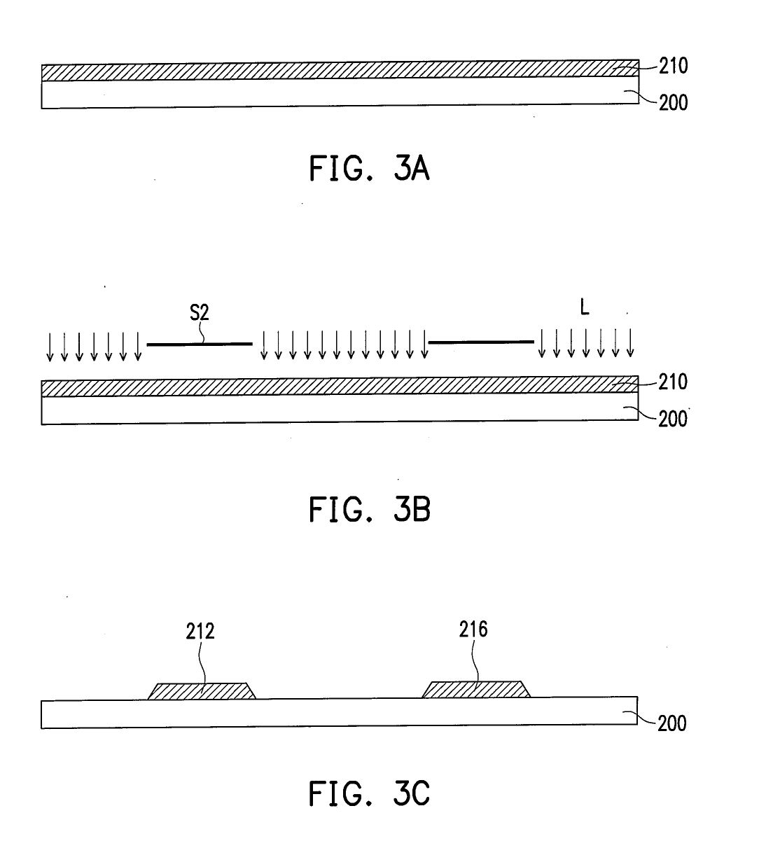

In addition, the method for forming the gate 212 (as illustrated in FIG. 2A) may include applying a laser ablation process, for example. FIG. 3A through 3C are schematic views illustrating a laser ablation process applied to form the gate.

Referring to FIG. 3A, a first metal layer 210 is formed on the substrate 200. Referring to FIG. 3B, a second shadow mask S2 is provided above the first metal layer 210, and the second shadow mask S2 exposes a portion of the first metal layer 210.

Afterwards, the laser L is applied to irradiate the first metal layer 210 via the second shadow mask S2 so as to remove the portion of the first metal layer 210 exposed by the second shadow mask S2. Finally, as illustrated in FIG. 3C, the remaining first metal layer 210 constitutes the gate 212 and the capacitor-bottom electrode 216.

According to another embodiment, a method for forming the gate 212 may also include the following steps. First, a first metal layer 210 is formed on the substrate 200, and then patterning the first metal layer 210 to form the gate 212 and the capacitor-bottom electrode 216. For example, the first metal layer 210 may be formed by a sputtering process, an evaporation process, or other thin film deposition processes, and patterned by a photolithographic process and an etching process.

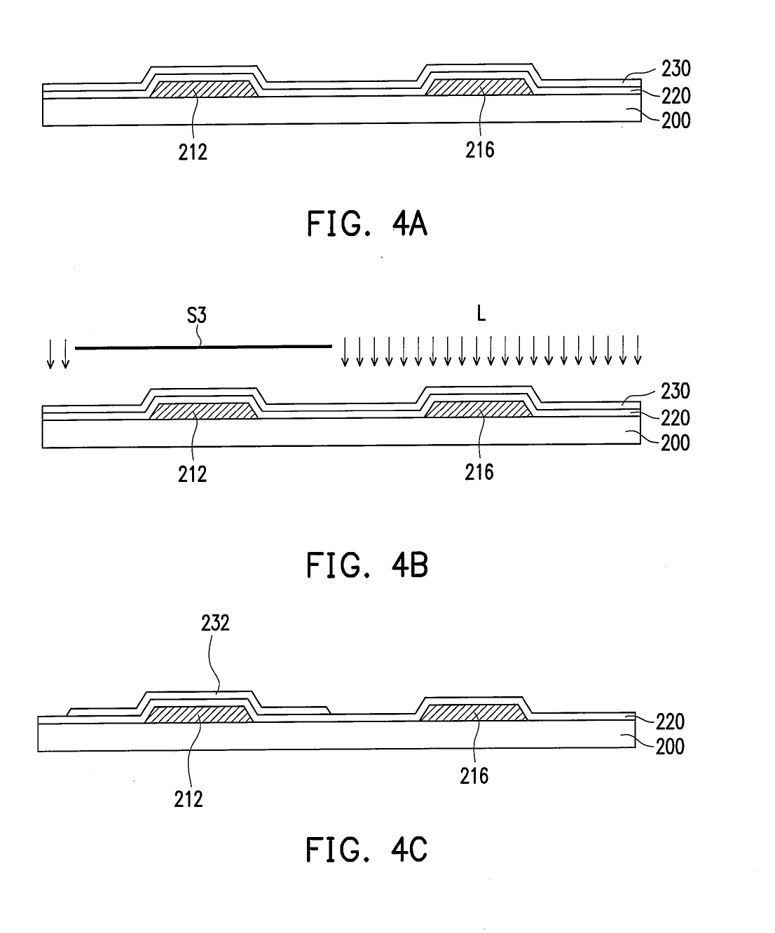

Additionally, the method for forming the channel layer 232 (as illustrated in FIG. 2B) may also include applying a laser ablation process, for example. FIG. 4A through 4C are schematic views illustrating a method for forming a channel layer.

Referring to FIG. 4A, a semiconductor layer 230 is formed on the gate dielectric layer 220. Next, as illustrated in FIG. 4B, a third shadow mask S3 is provided above the semiconductor layer 230, and the third shadow mask S3 exposes a portion of the semiconductor layer 230. Afterwards, the laser L is applied to irradiate the semiconductor layer 230 via the third shadow mask S3 so as to remove the portion of the semiconductor layer 230 exposed by the third shadow mask S3. As illustrated in FIG. 4C, the channel layer 232 is then formed on the gate dielectric layer 220 above the gate 212. In another embodiment, a method for forming the channel layer 232 is, for example, forming a semiconductor 230 on the gate dielectric layer 220 and then patterning the semiconductor layer 230 to form the channel layer 232. The semiconductor layer 230 is patterned by a photolithographic process and an etching process, for example. In the present embodiment, the semiconductor layer 230 may be made of amorphous silicon, polysilicon or other semiconductor materials.

Furthermore, in other embodiments of the present invention, an ohmic contact layer (not illustrated) may be first formed on a surface of the semiconductor layer 230.

Afterwards, an etching process is performed to remove a portion of the ohmic contact layer (not illustrated). For example, an N-type doped region may be formed on the surface of the semiconductor layer 230 by ion implantation so as to reduce the contact resistance between the channel layer 232 and the source 242 and contact resistance between the channel layer 232 and the drain 244.

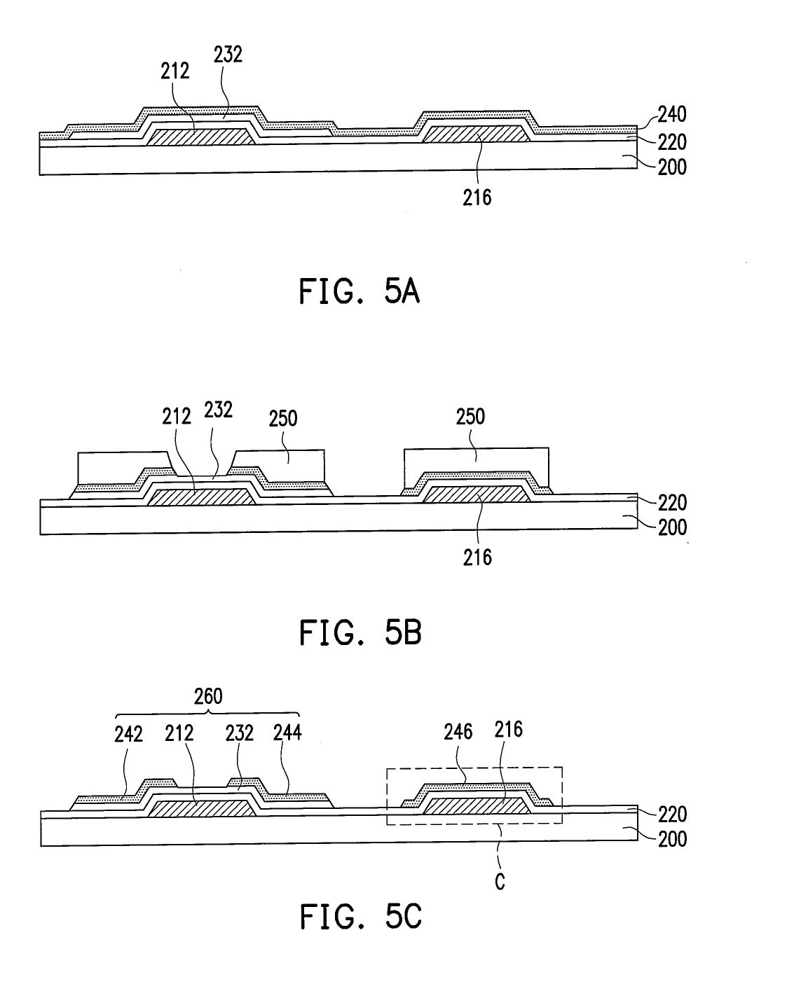

Moreover, the method for forming the source 242 and the drain 244 (as illustrated in FIG. 2C) may also be performing a photolithographic process and an etching process, for example. FIG. 5A through 5C are schematic views illustrating a method for forming a source and a drain. Referring to FIG. 5A first, a second metal layer 240 is formed on the channel layer 232 and the gate dielectric layer 220.

Referring to FIG. 5B, the second metal layer 240 is patterned. In detail, a patterned photoresist layer 250 is further formed above the channel layer 232 at the two sides of the gate 212, for example. The patterned photoresist layer 250 is then used as a mask to perform an etching process to remove a portion of the second metal layer 240 not covered by the patterned photoresist layer 250. After the patterned photoresist layer 250 is removed, the source 242 and the drain 244 are formed respectively on the channel layer 232 at the two sides of the gate 212 as illustrated in FIG. 5C. In the present embodiment, the patterned photoresist layer 250 is further formed on the second metal layer 240 above the capacitor-bottom electrode 216 so as to form the capacitor-top electrode 246 after an etching process. A material of the second metal layer 240 is, for example, aluminum (Al), molybdenum (Mo), titanium (Ti), neodymium (Nd) and nitride of any of the aforementioned, such as MoN, TiN, stacked layers thereof, and any alloy of the aforementioned or other conductive materials. In the present embodiment, the etching process may be a wet etching process, and in other embodiments, the etching process may also be a dry etching process. Furthermore, a process performed to remove the patterned photoresist layer 250 may be a wet etching process.

### The Second Embodiment

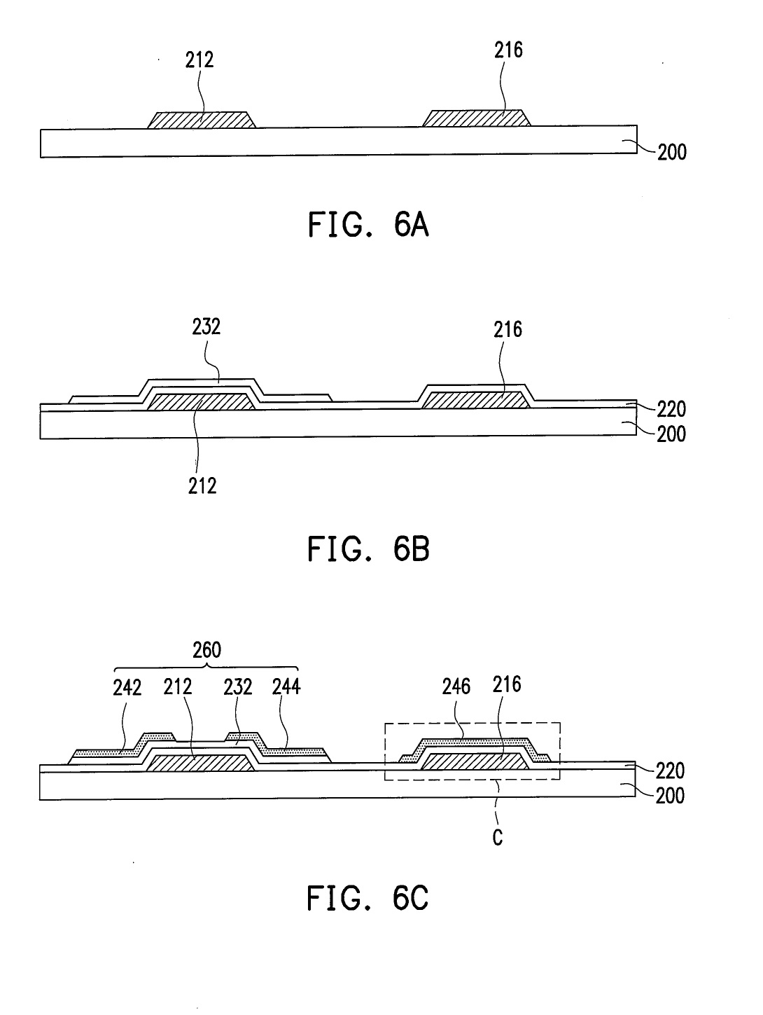

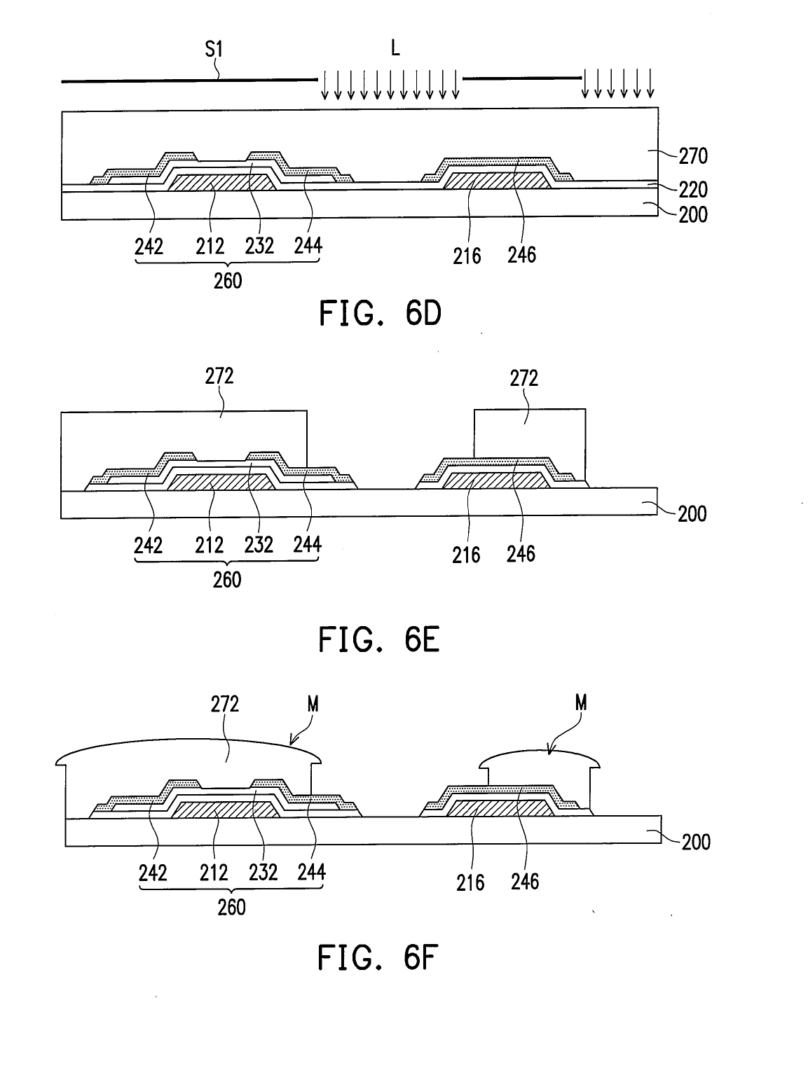

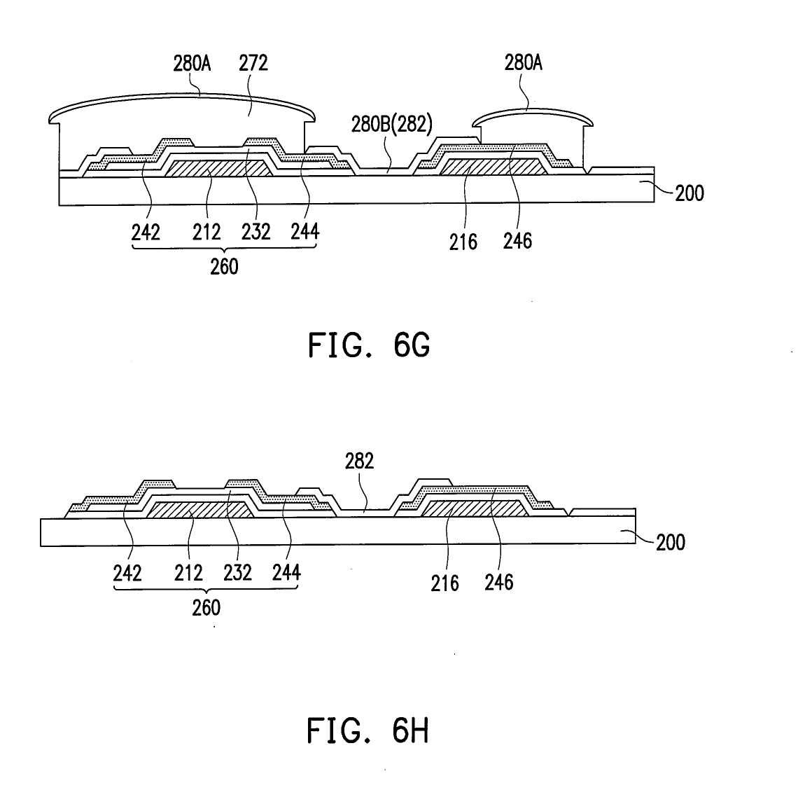

FIG. 6A through 6H are schematic views illustrating a method for fabricating a pixel structure according to the second embodiment of the present invention. Since steps illustrated in FIG. 6A through 6E are similar to those steps illustrated in FIG. 2A through 2E, a description of FIG. 6A through 6E is omitted herein.

Referring to FIG. 6F, the patterned passivation layer 272 is then baked to form a mushroom-shaped top surface M thereon. After baking, a pattern of the top surface of the patterned passivation layer 272 greater than a bottom surface thereof would appear so that the top surface of the patterned passivation layer 272 substantially presents the aforesaid mushroom-shaped top surface M. It should be noted that in practice, a shape of the patterned passivation layer 272 may have some deviation and alteration because of process variation during an actual baking process, such as a baking temperature, a heating speed, a heating time and the like. However, a pattern of the patterned passivation layer roughly presents the mushroom-shaped top surface greater than the bottom surface, and the shape of the top surface of the patterned passivation layer 272 is not limited to this.

Thereafter, referring to FIG. 6G, a conductive layer 280 is formed to cover the patterned passivation layer 272 and the exposed drain 244. A method for forming the conductive layer 280 may be sputtering an ITO (indium tin oxide) layer or an IZO (indium zinc oxide) layer. In FIG. 6G, since the patterned passivation layer 272 has the mushroom-shaped top surface M greater than the bottom surface, the two portions of conductive layers 280A and 280B electrically insulated from each other are formed when the conductive layer 280 is formed in the meantime. One portion of the conductive layer 280, the conductive layer 280A, is formed on the patterned passivation layer 272. The other portion of the conductive layer 280, the conductive layer 280B, is formed on the substrate 200, the drain 244 and a portion of the capacitor-top electrode 246. A portion of the conductive layer 280B connected with the drain 244 constitutes a pixel electrode 282 and is electrically connected to the capacitor-top electrode 246 simultaneously. It should be noted that in the present invention, distinct from the prior art, the patterned passivation layer 272 is designed to have a mushroom-shaped top surface M and the pixel electrode 282 is automatically defined while the conductive layer 280 is formed in the meanwhile. Therefore, a photolithography and etching process is omitted in the present invention and thereby reducing complexity of the fabricating process.

Generally, after the pixel electrode 282 is formed, the patterned passivation layer 272 may be further removed as illustrated in FIG. 6H. A method for removing the patterned passivation layer 272 includes, for example, applying a stripper to the surface of the patterned passivation layer 272 so that the bottom surface of the patterned passivation layer 272 ablates from the surface of the TFT 260 or the surface of the capacitor-top electrode 246 because the stripper permeates into the bottom surface of the passivation layer 272. A portion of the conductive layer 280A above the patterned passivation layer 272 can also be removed altogether simultaneously.

In view of the aforementioned, the fabricating method of the pixel electrode in the present invention differs from the conventional fabricating method of a pixel electrode applying a photolithography and etching process to form the conductive layer.

In the present invention, the pixel electrode is formed by directly patterning the conductive layer via a proper profile of the patterned passivation layer. Hence, the present invention has the advantage of reduced fabricating steps in comparison with the prior art. Further, a laser ablation process is applied to form the passivation layer in the present invention instead of the conventional lithographic process and etching process. Accordingly, the method for fabricating the pixel structure disclosed by the present invention at least has the following advantages:

In the method for fabricating the pixel structure of the present invention, a laser ablation process is applied to manufacture the pixel electrode instead of a photolithographic process. Therefore, compared with a high-precision photolithography and etching process required for a photolithographic process in the prior art, the fabricating cost of masks can be reduced in the present invention.

The present invention provides that fewer steps are involved in the fabricating process of the pixel structure in the present invention, and defects caused during the long photolithography and etching process of fabricating the pixel structure (such as photoresist coating, soft baking, hard baking, exposure, development, etching, photoresist stripping, and the like) are reduced.

The method for ablating the passivation layer via a laser ablation process may be applied to repairing a pixel electrode in pixel repairing. Thus, possible ITO residue is removed during the fabricating process of the pixel structure, a problem of short circuit between pixel electrodes is solved, and a process yield is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a pixel structure, comprising:
providing a substrate;
forming a gate on the substrate;
forming a gate dielectric layer on the substrate to cover the gate, forming a channel layer on the gate dielectric layer above the gate;
forming a source and a drain on the channel layer at two sides of the gate, wherein the gate, the channel layer, the source and the drain constitute a thin film transistor (TFT);
forming a passivation layer on the gate dielectric layer and the thin film transistor;
providing a first shadow mask above the passivation layer, the first shadow mask exposing a portion of the passivation layer;
applying a laser to irradiate the passivation layer via the first shadow mask to remove the exposed portion of the passivation layer so as to form a patterned passivation layer and expose the drain; and
forming a conductive layer to cover the patterned passivation layer and the drain, wherein the conductive layer is automatically patterned by the patterned passivation layer to form a pixel electrode. 2. The method as recited in claim 1, further comprising baking the patterned passivation layer after applying the laser to irradiate the passivation layer so that the patterned passivation layer has a mushroom-shaped top surface.

3. The method as recited in claim 2, wherein the mushroom-shaped top surface of the patterned passivation layer is greater than the bottom surface thereof.

4. The method as recited in claim 1, further comprising removing the patterned passivation layer after the conductive layer is formed.

5. The method as recited in claim 1, wherein a method for forming the gate comprises:
forming a first metal layer on the substrate; and
patterning the first metal layer to form the gate.

6. The method as recited in claim 1, wherein a method for forming the gate comprises:
forming a first metal layer on the substrate;
providing a second shadow mask above the first metal layer, wherein the second shadow mask exposes a portion of the first metal layer; and
applying a laser to irradiate the first metal layer via the second shadow mask so as to remove the portion of the first metal layer exposed by the second shadow mask.

7. The method as recited in claim 1, wherein a method for forming the channel layer comprises:
forming a semiconductor layer on the substrate; and
patterning the semiconductor layer to form the channel layer.

8. The method as recited in claim 1, wherein a method for forming the channel layer comprises:
forming a semiconductor layer on the substrate;
providing a third shadow mask above the semiconductor layer, wherein the third shadow mask exposes a portion of the semiconductor layer; and
applying a laser to irradiate the semiconductor layer via the third shadow mask so as to remove the portion of the semiconductor layer exposed by the third shadow mask.

9. The method as recited in claim 1, wherein a method for forming the source and the drain comprises:
forming a second metal layer on the channel layer and the gate dielectric layer; and
patterning the second metal layer to form the source and the drain.

10. The method as recited in claim 1, wherein a method for forming the conductive layer comprises sputtering an indium tin oxide (ITO) layer or an indium zinc oxide (IZO) layer.

11. The method as recited in claim 1, wherein a power of the laser is between about 10 mJ/cm² and about 500 mJ/cm².

12. The method as recited in claim 1, wherein a wavelength of the laser is between about 100 nm and about 400 nm.

13. The method as recited in claim 1, further comprising forming a capacitor-bottom electrode while forming the gate simultaneously and forming a capacitor-top electrode while forming the source and the drain simultaneously, wherein the capacitor-bottom electrode and the capacitor-top electrode constitute a storage capacitor.

14. A method for fabricating a pixel structure, comprising:
providing a substrate;
forming a thin film transistor (TFT) on the substrate;
forming a passivation layer on the thin film transistor;
providing a first shadow mask above the passivation layer, the first shadow mask exposing a portion of the passivation layer;
applying a laser to irradiate the passivation layer via the first shadow mask to remove the exposed portion of the passivation layer to form a patterned passivation layer and expose the drain; and
forming a conductive layer to cover the patterned passivation layer and the drain, wherein the conductive layer is automatically patterned by the patterned passivation layer to form a pixel electrode.

15. The method as recited in claim 14, further comprising baking the patterned passivation layer after applying the laser to irradiate the passivation layer so that the patterned passivation layer has a mushroom-shaped top surface.

16. The method as recited in claim 15, wherein the mushroom-shaped top surface of the patterned passivation layer is greater than the bottom surface thereof.

17. The method as recited in claim 14, further comprising removing the patterned passivation layer after the conductive layer is formed.
